(19) United States
(12) Patent Application Publication
(10) Pub. No.: US 2009/0122857 A1
(43) Pub. Date: May 14, 2009

(54) METHOD AND APPARATUS FOR PERFORMING RANK OVERRIDING IN LONG TERM EVOLUTION NETWORKS

(75) Inventors: Yingxue Li, Exton, PA (US); Donald M. Grieco, Manhasset, NY (US); Robert L. Olesen, Huntington, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL PATENT HOLDINGS, INC., Wilmington, DE (US)

(21) Appl. No.: 12/261,412

(22) Filed: Oct. 30, 2008

Related U.S. Application Data
(60) Provisional application No. 60/986,651, filed on Nov. 9, 2007.

(51) Int. Cl. H03K 7/04; H04L 1/02; H03K 7/06

(52) U.S. Cl. 375/239; 375/267

(57) ABSTRACT

Apparatus and method of generating a long term evolution (LTE) codebook and performing rank overriding are disclosed. Reordering rules are presented, whereby a second column vector of each rank-4 precoding matrix will not appear in column vectors of a rank-3 precoding matrix, and the first column vector of each rank-4 precodingmatrix is identical to the first column vector of the corresponding rank-3 precodingmatrix. Furthermore, precoder hopping between two precoding matrices corresponding to a particular precoding matrix index (PMI) is implemented, whereby a first one of the two precoding matrices comprises a first subset of column vectors of an original precoding matrix that corresponds to the particular PMI, and a second one of the two precoding matrices comprises a second subset of column vectors of the original precoding matrix. The precoder hopping is performed in time and/or frequency domain.

### CROSS REFERENCE TO RELATED APPLICATIONS

This application claims the benefit of U.S. Provisional Application No. 60/986,651 filed Nov. 9, 2007, which is incorporated by reference as if fully set forth.

### FIELD OF INVENTION

This application is related to wireless communications.

### BACKGROUND

Closed loop multiple-input multiple-output (MIMO) is an important operation mode in future long term evolution (LTE) networks. Under such a mode, a wireless transmit/receive unit (WTRU) feeds back a rank index (RI) and a precoding matrix index (PMI) to a base station, (i.e., an enhanced eNodeB (eNodeB)), along with channel quality indicator (CQI) information. In general, the base station responds to the WTRU feedback and sends downlink (DL) data accordingly. However, in certain circumstances, the base station may decide to override the RI feedback, and transmit DL data with a different rank than indicated by the WTRU feedback. Such an operation is referred to as rank overriding (RO).

For RO to perform properly, two conditions must be met:

1) The base station must derive a new precoding matrix for the newly selected rank; and

2) The base station must derive new CQI values for the newly derived precoding matrix so that proper modulation and coding schemes (MCS) may be assigned to each layer of MIMO transmission.

To meet the first condition, the LTE codebook forces a “nested property.” When the base station overrides the WTRU feedback rank with a lower rank, the “nested property” allows the base station to use a subset of the original precoding matrix as a new precoding matrix. According to the current LTE specification, it is difficult to derive an accurate CQI after the base station performs RO. Therefore, throughput after RO is reduced.

FIG. 1 shows a conventional LTE codebook 100 for systems equipped with four (4) transmit antennas. The LTE codebook 100 includes four columns 105, 110, 115 and 120, each having sixteen 4×4 precoding matrices W₀-W₁₅. Depending on the rank, all or a subset of column vectors of a 4×4 matrix is used as a precoding matrix. Column 105 is referred to as the rank-1 column of the codebook 100, column 110 is referred to as the rank-2 column of the codebook 100, column 115 is referred to as the rank-3 column of the codebook 100, and column 120 is referred to as the rank-4 column of the codebook 100. To feed back the information of the precoding matrix, a 2-bit RI and a 4-bit PMI are required. As shown in FIG. 1, the subscript of each 4×4 matrix represents the matrix index, and the superscript in brackets represents the column vectors. For example, W₀^{{14}} is a rank-2 precoding matrix consisting of the first and fourth column vectors of matrix W₀.

The following is an example illustrating the problem of current LTE codebook with four (4) transmit antennas and overriding operation. According to current channel conditions, the WTRU determined rank-4 can be accommodated, and the best precoding matrix (out of 16) is W₀. The WTRU then sends feedback PMI=0, and RI=3 (rank 4) to the base station. In the meantime, the WRTU also calculates CQI under the assumption RI=3 (rank 4), and PMI=0. According to the LTE specification, two codewords will be used for rank-4. Therefore, two CQI values must be calculated: CQI1 and CQI2. CQI1 is the channel quality indicator for the first codeword (CW1), which is split into first and second layers. CQI2 is the channel quality indicator for the second codeword (CW2), which is split into third and forth layers.

The channel matrix is H, and the effective channel vector is

\tilde{H}ₙ=HW₀^{{n}}_{.} Equation (1)

Although the exact formula to calculate CQI values may vary depending on the type of WTRU receivers, the channel quality of the first codeword (CQI1) is proportional to the average strength of \tilde{H}₁ and \tilde{H}₂, and the channel quality of the second codeword (CQI2) is proportional to the average strength of \tilde{H}₃ and \tilde{H}₄.

In this example, if the base station decides to transmit DL data with rank-3, (which is different than the WTRU feedback), it would select rank-3 precoding matrix Wₒ^{{124}} as the new precoding matrix. According to the codeword to layer mapping rule, the first codeword (CW₁) is mapped to the layer corresponding to the effective channel \tilde{H}₁, and the second codeword (CW₂) is mapped to the two layers corresponding to \tilde{H}₂ and \tilde{H}₄. The base station would then require a pair of new CQIs corresponding to the new precoding matrix. The new CQI values should be such that CQI1_RO is proportional to the strength of the effective channel \tilde{H}₁, and CQI2_RO is proportional to the average strength of the effective channels \tilde{H}₂ and \tilde{H}₄. The CQI1_RO is different than the original WTRU feedback CQI1, and the CQI2_RO is different than the original WTRU feedback CQI2. Consequently, with the current LTE codebook and codeword to layer mapping rule, it would be difficult for the base station to calculate CQI1_RO and CQI2_RO according to CQI1 and CQI2. Therefore, the base station will likely assign an improper MCS to each codeword, resulting inefficient transmission.

### SUMMARY

This application is related to an apparatus and method of generating an LTE codebook and performing rank overriding. Reordering rules are presented, whereby a second column vector of each rank-4 precoding matrix will not appear in column vectors of a rank-3 precoding matrix, and the first column vector of each rank-4 precoding matrix is identical to the first column vector of the corresponding rank-3 precoding matrix. Furthermore, precoder hopping between two precoding matrices corresponding to a particular PMI is implemented, whereby a first one of the two precoding matrices comprises a first subset of column vectors of an original precoding matrix that corresponds to the particular PMI, and a second one of the two precoding matrices comprises a second subset of column vectors of the original precoding matrix. The precoder hopping is performed in time and/or frequency domain.

### BRIEF DESCRIPTION OF THE DRAWINGS

A more detailed understanding may be had from the following description, given by way of example and to be understood in conjunction with the accompanying drawings wherein:

FIG. 1 shows a conventional LTE codebook with a rank-4 precoding matrix;

FIG. 2 shows a new LTE codebook with a modified rank-4 precoding matrix;

FIG. 3 shows rank overriding with precoder hopping in frequency domain;

FIG. 4 shows rank overriding with precoder hopping in time domain;

FIG. 5 shows rank overriding with precoder hopping in both time and frequency domain;

FIG. 6 shows a precoder hopping rule for rank overriding;

FIG. 7A shows a conventional PMI independent rank-4 layer mapping;

FIG. 7B shows a proposed PMI dependent rank-4 layer mapping;

FIG. 8 is a block diagram of a WTRU; and

FIG. 9 is a block diagram of a base station.

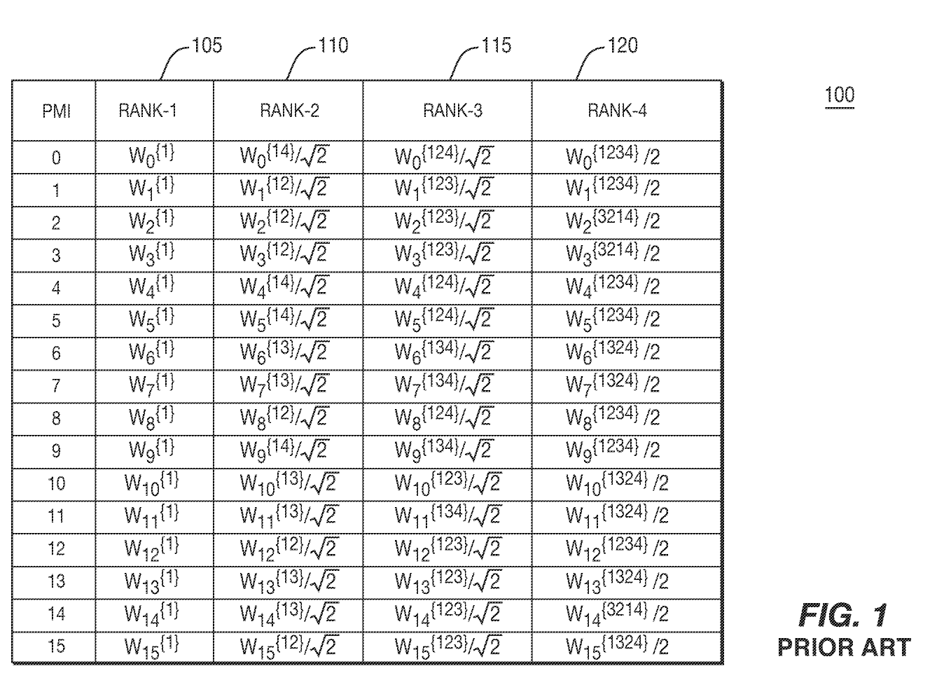

### DETAILED DESCRIPTION

When referred to hereafter, the terminology “wireless transmit/receive unit (WTRU)” includes but is not limited to a user equipment (UE), a mobile station, a fixed or mobile subscriber unit, a pager, a cellular telephone, a personal digital assistant (PDA), a computer, or any other type of user device capable of operating in a wireless environment.

When referred to hereafter, the terminology “base station” includes but is not limited to an evolved or E-UTRAN Node-B (eNodeB), a site controller, an access point (AP), or any other type of interfacing device capable of operating in a wireless environment.

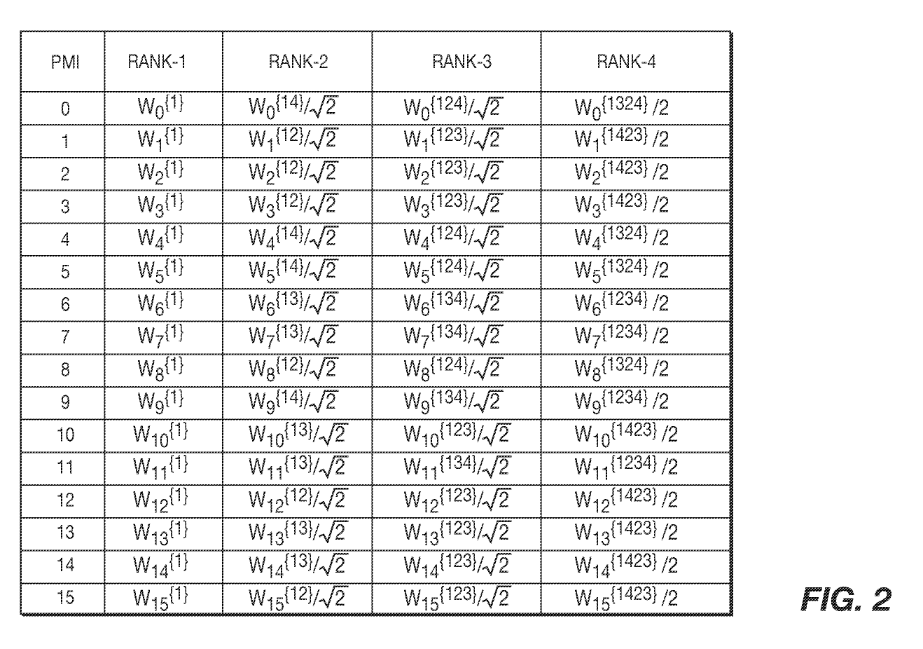

One method of improving the data transmission after rank overriding is to change the order of the column vector in a rank-4 precoding matrix. FIG. 2 shows an example of a new codebook with a modified rank-4 precoding matrix. The advantage of changing only the order of the column vector is that the performance of rank-4 precoding is not affected.

New reordering rules are proposed herein, whereby the second column vector of each rank-4 precoding matrix will not appear in the column vectors of the rank-3 precoding matrix, and the first column vector of each rank-4 precoding matrix is identical to the first column vector of the corresponding rank-3 precoding matrix.

Using the example above, the CQI1 calculated by the WTRU is proportional to the average strength of \tilde{H}₁ and \tilde{H}₃, and the CQI2 calculated by the WTRU is proportional to the average strength of \tilde{H}₂ and \tilde{H}₄. In this example, the CQI2 is consistent with CQI2_RO. Therefore, the base station can use the WTRU feedback on CQI2, without modification, in assigning a MCS to the second codeword, without causing performance degradation to CW2. However, the CQI1 definition differs from CQI1_RO, even after modification of rank-4 precoding matrices.

Precoding hopping after rank overriding will now be described. Under the current LTE codebook definition and codeword to layer mapping, rank overriding is performed by arbitrarily removing one or more column vector(s) from the original precoding matrix fed back by WTRU. Therefore, it is then possible that column vectors corresponding to satisfactory channel quality are removed. This also causes CQI discrepancy between the WTRU and base station. In the proposed precoding hopping scheme, all column vectors of the original precoding matrix are used to precode DL data, even after rank overriding. Since the number of column vectors is larger than the rank, the base station switches the precoding matrix in either time and/or frequency domain.

The following example describes rank 4 to rank 3 overriding to illustrate the concept of precoder hopping after rank overriding. The W₀^{{1324}} is the original rank-4 precoding matrix fed back by the WTRU. To override the rank to 3, the current LTE specification would use Wₒ^{{124}} as the rank-3 precoding matrix in all orthogonal frequency division multiplexing (OFDM) symbols and all subcarriers.

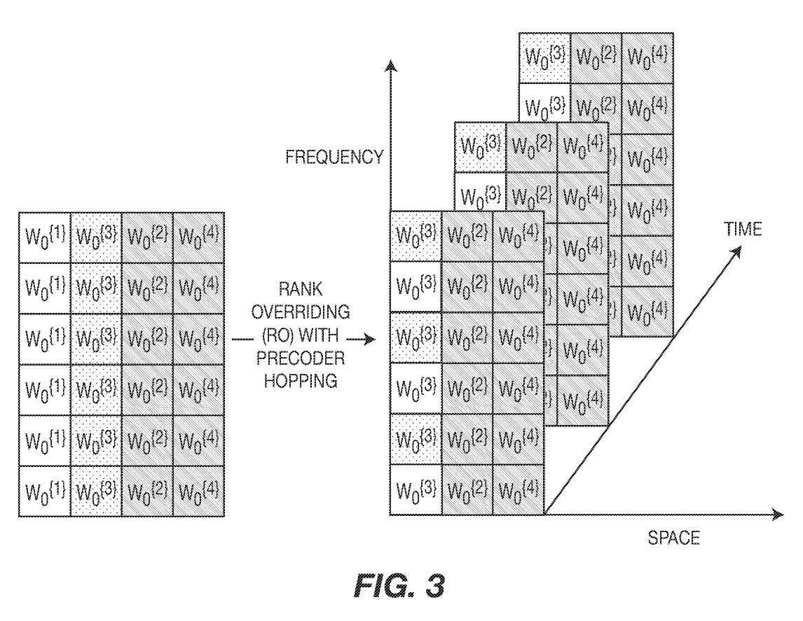

FIG. 3 shows an example of rank overriding with frequency domain precoder hopping, where the base station alternates the precoding matrix W₀^{{124}} and W₀^{{324}} in frequency. The precoding matrix W₀^{{124}} is applied in odd subcarriers, and the precoding matrix W₀^{{324}} is applied in even subcarriers.

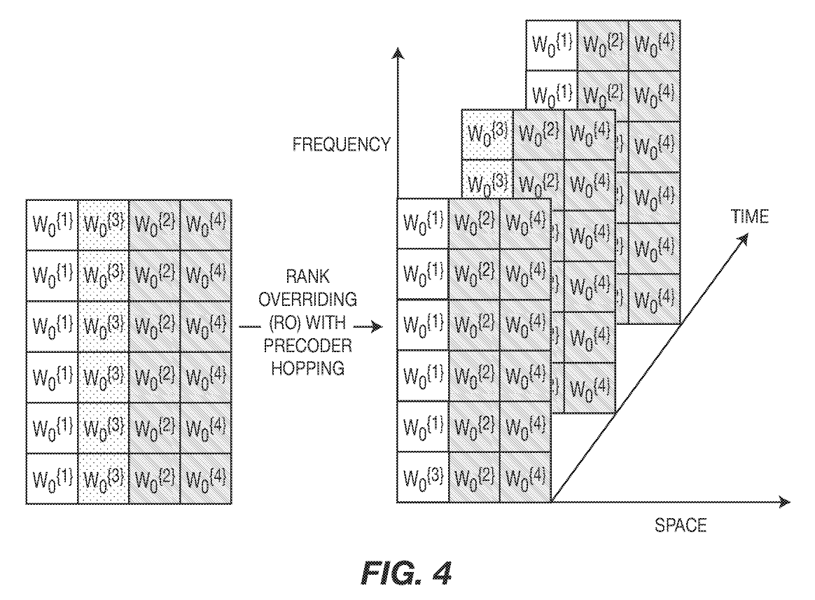

Similarly, the precoder hopping can be done in time domain, as shown in FIG. 4. Within the same precoding group (PCG), the precoding matrix W₀^{{124}} is applied on all subcarriers of the odd OFDM symbols, and the precoding matrix W₀^{{324}} is applied on all subcarriers of the even ODFM symbols.

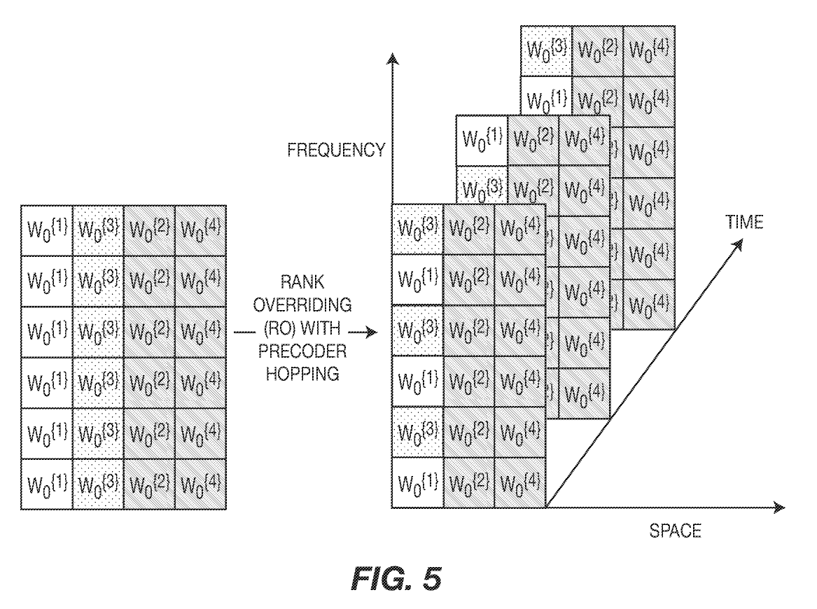

In addition, the precoder hopping can be performed in both time and frequency domain simultaneously as shown in FIG. 5, where the precoding matrix W₀^{{124}} is applied on all of the odd subcarriers of odd OFDM symbols, and all of the even subcarriers of even OFDM symbols, and the precoding matrix W₀^{{324}} is applied on all of the even subcarriers of odd OFDM symbols, and all of the odd subcarriers of even OFDM symbols.

All of the precoder hopping patterns shown in FIGS. 3-5 confirm that after rank overriding, the CQI for the first codeword CQI1_RO is the average strength of \tilde{H}₁ and \tilde{H}₃, which is consistent with CQI1 before rank overriding.

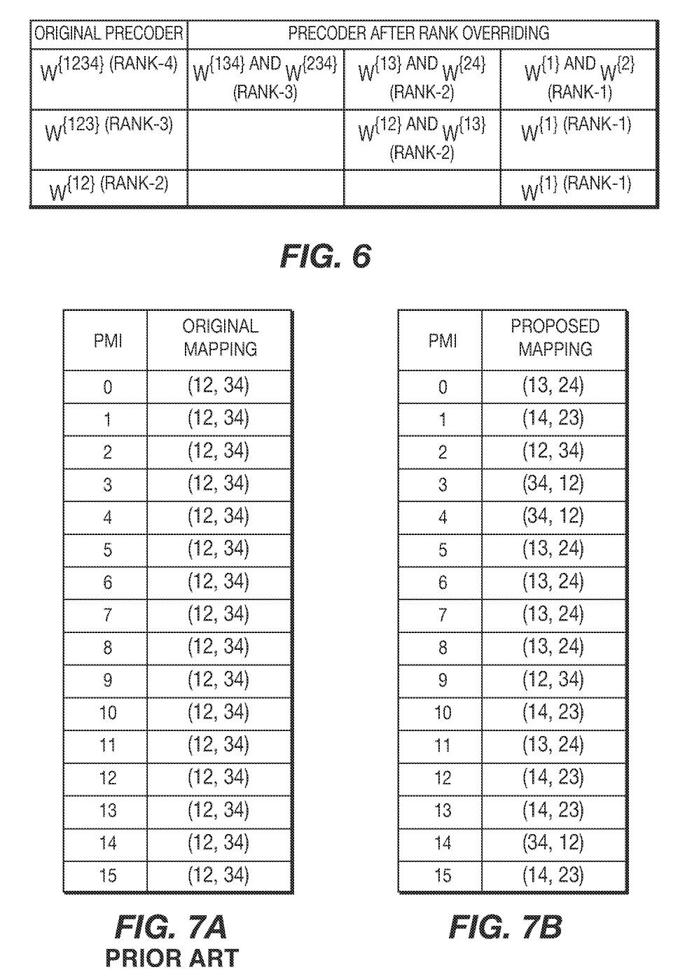

Rank overriding is not limited to only rank-4 to rank-3 overriding. FIG. 6 shows a table that summarizes the precoder hopping pattern for other rank overriding scenarios. As shown in FIG. 6, two different precoding matrices may be used after rank overriding in some circumstances. In such cases, two precoders are used alternately in either frequency or/and time domain. For example, if the base station decides to override rank-4 with rank-2, two precoding matrices will be used alternate, (i.e., hopping), between matrices after the rank overriding, whereby the first matrix comprises the first and third column vectors of the original rank-4 matrix, and the second matrix comprises the second and fourth column vectors of the original rank-4 matrix. In another example, if the base station decides to override rank-3 with rank-2, two precoding matrices will alternate, (i.e., hop), between matrices after the rank overriding, whereby the first matrix comprises the first and second column vectors of the original rank-3 matrix, and the second matrix comprises the first and third column vectors of the original rank-3 matrix. In yet another example, if the base station decides to override rank-3 with rank-1, then no precoder hopping is necessary as only one precoding matrix exists in such a case.

The order of the column vectors of rank-4 precoding matrices may be changed, which maintains the current codeword to layer mapping, or the rank-4 precoding matrices can remain unchanged, while changing the fixed rank-4 codeword to layer mapping to PMI dependent mapping, as shown in FIG. 6.

In the original mapping shown in FIG. 7A, the first codeword is mapped to the first and second layers (12), and the second codeword is mapped to the third and fourth layers (34), regardless of the PMI value 0-15. FIG. 7B shows an example of a modified mapping, whereby the first codeword is mapped to the first and third layers (13), and the second is mapped to the second and fourth layers (24) when the PMI value is 0. When the PMI value is 1, the first codeword is mapped to the first and fourth layers, and the second codeword is mapped to the second and third layers. It is noted that different PMI dependent layer mapping is also possible. However, in this case, the precoding vectors corresponding to the second codeword in rank-4 should also be applied to the second codeword in rank-3.

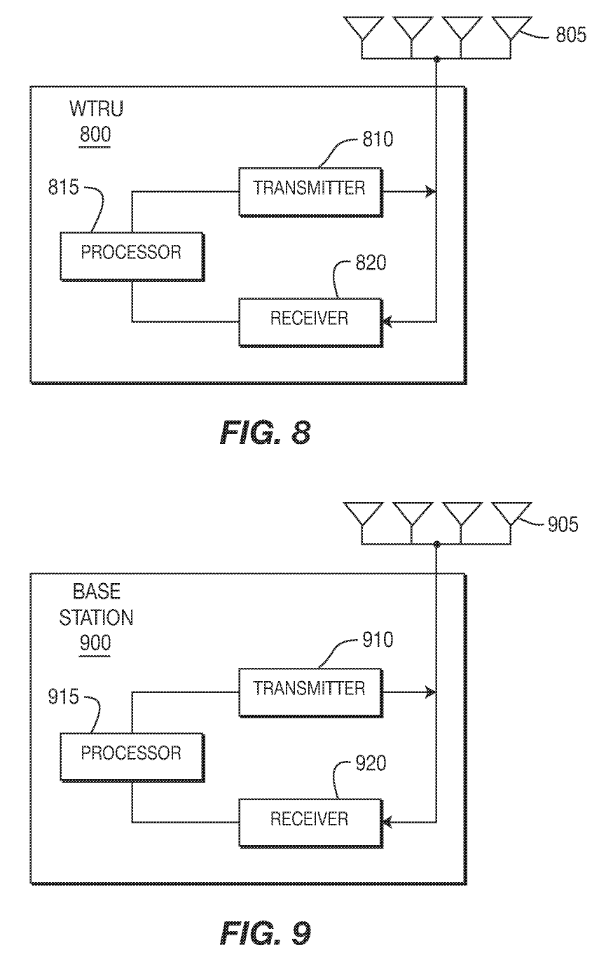

FIG. 8 shows a WTRU 800 comprising a MIMO antenna 805, a transmitter 810, a processor 815 and a receiver 820. The WTRU 800 may be configured to generate an LTE codebook having a rank-1 column, a rank-2 column, a rank-3 column and a rank-4 column. Each column includes a plurality of precoding matrices. Each precoding matrix corresponds to a respective PMI. The LTE codebook may have sixteen (16) different PMIs. Furthermore, the first column vector of each precoding matrix in the rank-4 column that corresponds to a particular PMI may be the same as the first column vector in a precoding matrix in the rank-3 column that also corresponds to the particular PMI.

The processor 815 may be configured to assign a first column vector to each of the precoding matrices in the rank-1 column, assign a first column vector and a second column vector to each of the precoding matrices in the rank-2 column, assign a first column vector, a second column vector and a third column vector to each of the precoding matrices in the rank-3 column, and assign a first column vector, a second column vector, a third column vector and a fourth column vector to each of the precoding matrices in the rank-4 column. Either the second or third column vector of each precoding matrix in the rank-3 column that corresponds to a particular PMI is the same as the second column vector in a precoding matrix in the rank-2 column that also corresponds to the particular PMI. The last two column vectors of each precoding matrix in the rank-4 column that corresponds to a particular PMI are the same as the last two column vectors in the rank-3 column for the particular PMI. The second column vector of any precoding matrix in the rank-4 column that corresponds to a particular PMI is not included in a precoding matrix in the rank-3 column that also corresponds to the particular PMI.

The WTRU 800 may also be configured to perform rank overriding using frequency domain precoder hopping in an LTE codebook having a rank-1 column, a rank-2 column, a rank-3 column and a rank-4 column. Each column includes a plurality of precoding matrices having column vectors assigned thereto. Each precoding matrix corresponds to a respective PMI. The processor 815 may be configured to alternate between the use of two precoding matrices corresponding to a particular PMI. A first one of the two precoding matrices comprises a first subset of column vectors of an original precoding matrix that corresponds to the particular PMI, and a second one of the two precoding matrices comprises a second subset of column vectors of the original precoding matrix. The alternation between the use of two precoding matrices is implemented by precoder hopping that is performed in time domain and/or frequency domain.

In one scenario, the first one of two precoding matrices is applied on odd subcarriers of each OFDM symbol, and the second one of two precoding matrices is applied on even subcarriers of each OFDM symbol.

In another scenario, the first one of the two precoding matrices may be applied on all subcarriers of odd orthogonal OFDM symbols, and the second one of the two precoding matrices is applied on all subcarriers of even OFDM symbols.

In yet another scenario, the first one of the two precoding matrices may be applied on all odd subcarriers of odd OFDM symbols, and on all even subcarriers of even OFDM symbols. The second one of the two precoding matrices may be applied on all even subcarriers of odd OFDM symbols, and on all odd subcarriers of even OFDM symbols.

FIG. 9 shows a base station 900 comprising a MIMO antenna 905, a transmitter 910, a processor 915 and a receiver 920. The base station 900 may be configured to generate an LTE codebook having a rank-1 column, a rank-2 column, a rank-3 column and a rank-4 column. Each column includes a plurality of precoding matrices. Each precoding matrix corresponds to a respective PMI. The LTE codebook may have sixteen (16) different PMIs. Furthermore, the first column vector of each precoding matrix in the rank-4 column that corresponds to a particular PMI may be the same as the first column vector in a precoding matrix in the rank-3 column that also corresponds to the particular PMI.

The processor 915 may be configured to assign a first column vector to each of the precoding matrices in the rank-1 column, assign a first column vector and a second column vector to each of the precoding matrices in the rank-2 column, assign a first column vector, a second column vector and a third column vector to each of the precoding matrices in the rank-3 column, and assign a first column vector, a second column vector, a third column vector and a fourth column vector to each of the precoding matrices in the rank-4 column. The second column vector of any precoding matrix in the rank-4 column that corresponds to a particular PMI is not included in a precoding matrix in the rank-3 column that also corresponds to the particular PMI. The base station 900 may also be configured to perform rank overriding using frequency domain precoder hopping in an LTE codebook having a rank-1 column, a rank-2 column, a rank-3 column and a rank-4 column. Each column includes a plurality of precoding matrices having column vectors assigned thereto. Each precoding matrix corresponds to a respective PMI. The processor 915 may be configured to alternate between the use of two precoding matrices corresponding to a particular PMI. A first one of the two precoding matrices comprises a first subset of column vectors of an original precoding matrix that corresponds to the particular PMI, and a second one of the two precoding matrices comprises a second subset of column vectors of the original precoding matrix. The alternation between the use of two precoding matrices is implemented by precoder hopping that is performed in time domain and/or frequency domain.

In one scenario, the first one of two precoding matrices is applied on odd subcarriers of each OFDM symbol, and the second one of two precoding matrices is applied on even subcarriers of each OFDM symbol.

In another scenario, the first one of the two precoding matrices may be applied on all subcarriers of odd orthogonal OFDM symbols, and the second one of the two precoding matrices is applied on all subcarriers of even OFDM symbols.

In yet another scenario, the first one of the two precoding matrices may be applied on all odd subcarriers of odd OFDM symbols, and on all even subcarriers of even OFDM symbols. The second one of the two precoding matrices may be applied on all even subcarriers of odd OFDM symbols, and on all odd subcarriers of even OFDM symbols.

Although the features and elements are described in particular combinations, each feature or element can be used alone without the other features and elements or in various combinations with or without other features and elements. The methods or flow charts provided may be implemented in a computer program, software, or firmware tangibly embodied in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

A processor in association with software may be used to implement a radio frequency transceiver for use in a wireless transmit/receive unit (WTRU), user equipment (UE), terminal, base station, radio network controller (RNC), or any host computer. The WTRU may be used in conjunction with modules, implemented in hardware and/or software, such as a camera, a video camera module, a videophone, a speakerphone, a vibration device, a speaker, a microphone, a television transceiver, a hands free headset, a keyboard, a Bluetooth® module, a frequency modulated (FM) radio unit, a liquid crystal display (LCD) display unit, an organic light-emitting diode (OLED) display unit, a digital music player, a media player, a video game player module, an Internet browser, and/or any wireless local area network (WLAN) module.

What is claimed is:

1. A wireless communication method of generating a long term evolution (LTE) codebook having a rank-1 column, a rank-2 column, a rank-3 column and a rank-4 column, each column including a plurality of precoding matrices, each precoding matrix corresponding to a respective precoding matrix index (PMI), the method comprising:
assigning a first column vector to each of the precoding matrices in the rank-1 column;
assigning a first column vector and a second column vector to each of the precoding matrices in the rank-2 column;
assigning a first column vector, a second column vector and a third column vector to each of the precoding matrices in the rank-3 column; and
assigning a first column vector, a second column vector, a third column vector and a fourth column vector to each of the precoding matrices in the rank-4 column, wherein the second column vector of any precoding matrix in the rank-4 column that corresponds to a particular PMI is not included in a precoding matrix in the rank-3 column that also corresponds to the particular PMI.

2. The method of claim 1 wherein the LTE codebook has sixteen different PMIs.

3. A wireless communication method of generating a long term evolution (LTE) codebook having a rank-1 column, a rank-2 column, a rank-3 column and a rank-4 column, each column including a plurality of precoding matrices, each precoding matrix corresponding to a respective precoding matrix index (PMI), the method comprising:
assigning a first column vector to each of the precoding matrices in the rank-1 column;
assigning a first column vector and a second column vector to each of the precoding matrices in the rank-2 column;
assigning a first column vector, a second column vector and a third column vector to each of the precoding matrices in the rank-3 column, wherein either the second or third column vector of each precoding matrix in the rank-3 column that corresponds to a particular PMI is the same as the second column vector in a precoding matrix in the rank-2 column that also corresponds to the particular PMI; and
assigning a first column vector, a second column vector, a third column vector and a fourth column vector to each of the precoding matrices in the rank-4 column, wherein the first column vector of each precoding matrix in the rank-4 column that corresponds to a particular PMI is the same as the first column vector in a precoding matrix in the rank-3 column that also corresponds to the particular PMI, and the last two column vectors of each precoding matrix in the rank-4 column that corresponds to a particular PMI are the same as the last two column vectors in the rank-3 column for the particular PMI.

4. The method of claim 3 wherein the LTE codebook has sixteen different PMIs.

5. A wireless communication method of performing rank overriding using frequency domain precoder hopping in a long term evolution (LTE) codebook having a rank-1 column, a rank-2 column, a rank-3 column and a rank-4 column, each column including a plurality of precoding matrices having column vectors assigned thereto, each precoding matrix corresponding to a respective precoding matrix index (PMI), the method comprising:
alternating between the use of two precoding matrices corresponding to a particular PMI, whereby a first one of the two precoding matrices comprises a first subset of column vectors of an original precoding matrix that corresponds to the particular PMI, and a second one of the two precoding matrices comprises a second subset of column vectors of the original precoding matrix,

6. The method of claim 5 wherein the alternating is implemented by precoder hopping that is performed in time domain.

7. The method of claim 6 wherein the first one of the two precoding matrices is applied on all subcarriers of odd orthogonal frequency division multiplexing (OFDM) symbols, and the second one of the two precoding matrices is applied on all subcarriers of even OFDM symbols.

8. The method of claim 5 wherein the alternating is precoder hopping that is performed in frequency domain.

9. The method of claim 5 wherein the alternating is precoder hopping that is performed in frequency and time domain.

10. The method of claim 9 wherein the first one of the two precoding matrices is applied on all odd subcarriers of odd orthogonal frequency division multiplexing (OFDM) symbols, and on all even subcarriers of even OFDM symbols, and the second one of the two precoding matrices is applied on all even subcarriers of odd OFDM symbols, and on all odd subcarriers of even OFDM symbols.

11. A wireless transmit/receive unit (WTRU) configured to generate a long term evolution (LTE) codebook having a rank-1 column, a rank-2 column, a rank-3 column and a rank-4 column, each column including a plurality of precoding matrices, each precoding matrix corresponding to a respective precoding matrix index (PMI), the WTRU comprising:
a multiple-input multiple-output (MIMO) antenna; and
a processor configured to:
assign a first column vector to each of the precoding matrices in the rank-1 column;
assign a first column vector and a second column vector to each of the precoding matrices in the rank-2 column;
assign a first column vector, a second column vector and a third column vector to each of the precoding matrices in the rank-3 column; and
assign a first column vector, a second column vector, a third column vector and a fourth column vector to each of the precoding matrices in the rank-4 column, wherein the second column vector of any precoding matrix in the rank-4 column that corresponds to a particular PMI is not included in a precoding matrix in the rank-3 column that also corresponds to the particular PMI.

12. The WTRU of claim 11 wherein the LTE codebook has sixteen different PMIs.

13. A wireless transmit/receive unit (WTRU) configured to generate a long term evolution (LTE) codebook having a rank-1 column, a rank-2 column, a rank-3 column and a rank-4 column, each column including a plurality of precoding matrices, each precoding matrix corresponding to a respective precoding matrix index (PMI), the WTRU comprising:
a multiple-input multiple-output (MIMO) antenna; and
a processor configured to:
assign a first column vector to each of the precoding matrices in the rank-1 column;
assign a first column vector and a second column vector to each of the precoding matrices in the rank-2 column;
assign a first column vector, a second column vector and a third column vector to each of the precoding matrices in the rank-3 column, wherein either the second or third column vector of each precoding matrix in the rank-3 column that corresponds to a particular PMI is the same as the second column vector in a precoding matrix in the rank-2 column that also corresponds to the particular PMI; and
assign a first column vector, a second column vector, a third column vector and a fourth column vector to each of the precoding matrices in the rank-4 column, wherein the first column vector of each precoding matrix in the rank-4 column that corresponds to a particular PMI is the same as the first column vector in a precoding matrix in the rank-3 column that also corresponds to the particular PMI and the last two column vectors of each precoding matrix in the rank-4 column that corresponds to a particular PMI are the same as the last two column vectors in the rank-3 column for the particular PMI.

14. The WTRU of claim 13 wherein the LTE codebook has sixteen different PMIs.

15. A wireless transmit/receive unit (WTRU) configured to perform rank overriding using frequency domain precoder hopping in a long term evolution (LTE) codebook having a rank-1 column, a rank-2 column, a rank-3 column and a rank-4 column, each column including a plurality of precoding matrices having column vectors assigned thereto, each precoding matrix corresponding to a respective precoding matrix index (PMI), the WTRU comprising:
a multiple-input multiple-output (MIMO) antenna; and
a processor configured to alternate between the use of two precoding matrices corresponding to a particular PMI, whereby a first one of the two precoding matrices comprises a first subset of column vectors of an original precoding matrix that corresponds to the particular PMI, and a second one of the two precoding matrices comprises a second subset of column vectors of the original precoding matrix,

16. The WTRU of claim 15 wherein the alternating is implemented by precoder hopping that is performed in time domain.

17. The WTRU of claim 16 wherein the first one of the two precoding matrices is applied on all subcarriers of odd orthogonal frequency division multiplexing (OFDM) symbols, and the second one of the two precoding matrices is applied on all subcarriers of even OFDM symbols.

18. The WTRU of claim 15 wherein the alternating is precoder hopping that is performed in frequency domain.

19. The WTRU of claim 15 wherein the alternating is precoder hopping that is performed in frequency and time domain.

20. The WTRU of claim 19 wherein the first one of the two precoding matrices is applied on all odd subcarriers of odd orthogonal frequency division multiplexing (OFDM) symbols, and on all even subcarriers of even OFDM symbols, and the second one of the two precoding matrices is applied on all even subcarriers of odd OFDM symbols, and on all odd subcarriers of even OFDM symbols.

21. A base station configured to generate a long term evolution (LTE) codebook having a rank-1 column, a rank-2 column, a rank-3 column and a rank-4 column, each column including a plurality of precoding matrices, each precoding matrix corresponding to a respective precoding matrix index (PMI), the base station comprising:
a multiple-input multiple-output (MIMO) antenna; and
a processor configured to:
assign a first column vector to each of the precoding matrices in the rank-1 -column;
assign a first column vector and a second column vector to each of the precoding matrices in the rank-2 column;
assign a first column vector, a second column vector and a third column vector to each of the precoding matrices in the rank-3 column; and
assign a first column vector, a second column vector, a third column vector and a fourth column vector to each of the precoding matrices in the rank-4 column, wherein the second column vector of any precoding matrix in the rank-4 column that corresponds to a particular PMI is not included in a precoding matrix in the rank-3 column that also corresponds to the particular PMI.

22. The base station of claim 21 wherein the LTE codebook has sixteen different PMIs.

23. A base station configured to generate a long term evolution (LTE) codebook having a rank-1 column, a rank-2 column, a rank-3 column and a rank-4 column, each column including a plurality of precoding matrices, each precoding matrix corresponding to a respective precoding matrix index (PMI), the base station comprising:
a multiple-input multiple-output (MIMO) antenna; and
a processor configured to:
assign a first column vector to each of the precoding matrices in the rank-1 column;
assign a first column vector and a second column vector to each of the precoding matrices in the rank-2 column;
assign a first column vector, a second column vector and a third column vector to each of the precoding matrices in the rank-3 column, wherein either the second or third column vector of each precoding matrix in the rank-3 column that corresponds to a particular PMI is the same as the second column vector in a precoding matrix in the rank-2 column that also corresponds to the particular PMI; and
assign a first column vector, a second column vector, a third column vector and a fourth column vector to each of the precoding matrices in the rank-4 column, wherein the first column vector of each precoding matrix in the rank-4 column that corresponds to a particular PMI is the same as the first column vector in a precoding matrix in the rank-3 column that also corresponds to the particular PMI and the last two column vectors of each precoding matrix in the rank-4 column that corresponds to a particular PMI are the same as the last two column vectors in the rank-3 column for the particular PMI.

24. The base station of claim 23 wherein the LTE codebook has sixteen different PMIs.

25. A base station configured to perform rank overriding using frequency domain precoder hopping in a long term evolution (LTE) codebook having a rank-1 column, a rank-2 column, a rank-3 column and a rank-4 column, each column including a plurality of precoding matrices having column vectors assigned thereto, each precoding matrix corresponding to a respective precoding matrix index (PMI), the base station comprising:
a multiple-input multiple-output (MIMO) antenna; and
a processor configured to alternate between the use of two precoding matrices corresponding to a particular PMI, whereby a first one of the two precoding matrices comprises a first subset of column vectors of an original precoding matrix that corresponds to the particular PMI, and a second one of the two precoding matrices comprises a second subset of column vectors of the original precoding matrix,

26. The base station of claim 25 wherein the alternating is implemented by precoder hopping that is performed in time domain.

27. The base station of claim 26 wherein the first one of the two precoding matrices is applied on all subcarriers of odd orthogonal frequency division multiplexing (OFDM) symbols, and the second one of the two precoding matrices is applied on all subcarriers of even OFDM symbols.

28. The base station of claim 25 wherein the alternating is precoder hopping that is performed in frequency domain.

29. The base station of claim 25 wherein the alternating is precoder hopping that is performed in frequency and time domain.

30. The base station of claim 29 wherein the first one of the two precoding matrices is applied on all odd subcarriers of odd orthogonal frequency division multiplexing (OFDM) symbols, and on all even subcarriers of even OFDM symbols, and the second one of the two precoding matrices is applied on all even subcarriers of odd OFDM symbols, and on all odd subcarriers of even OFDM symbols.
